(19) United States
(12) Patent Application Publication
(10) Pub. No.: US 2025/0204034 A1
(43) Pub. Date: Jun. 19, 2025

(54) STRUCTURES FOR STACKED-FET ANALOG APPLICATIONS

(71) Applicant: INTERNATIONAL BUSINESS MACHINES CORPORATION, ARMONK, NY (US)

(72) Inventors: Terence B. Hook, Jericho Center, VT (US); Blaine Jeffrey Gross, Essex Junction, VT (US)

(21) Appl. No.: 18/540,856

(22) Filed: Dec. 14, 2023

(51) Int. Cl. H01L 27/092; H01L 29/06; H01L 29/423; H01L 29/775; H01L 29/786; H03K 17/687

(52) U.S. Cl. CPC H10D 84/85; H10D 30/43; H10D 30/6735; H10D 30/6757; H10D 62/121; H03K 17/6871

(57) ABSTRACT

A microelectronic structure includes a nanosheet transistor device stack having a first transistor device stacked on a second transistor device. The first transistor device includes a source and drain. The second transistor device includes terminal connections. A gate is shared between the first transistor device and the second transistor device. The first transistor device is configured to conduct a current between the drain and the source based on a voltage on the gate. The terminal connections of the second transistor device are vestigial irrespective of a voltage applied to the gate, such that the second transistor device is always passive.

### BACKGROUND

### Technical Field

The present disclosure generally relates to semiconductor device architecture, and more particularly, to structures for stacked-FET analog applications.

### Description of the Related Art

Burgeoning computing structures benefit from advances in microelectronic devices that are capable of handling combinatorial logic processes. For example, devices using nanosheet stacked field effect transistors (FETs) are able to handle more complex logic flows than their predecessors due to the plurality of transistors available on any one given device. Logic signals are able to flow into a device and be processed by any one of a number of transistor elements available. Conventionally, stacked FET devices are manufactured in pairs that include both a PFET and NFET that are tied to each other. The pairs provide for conventional logic operations that use both PFETs and NFETs. However, there are circuit applications such as analog signal processing, that do not typically employ NFETs and PFETS as pairs with a common gate. While the logic fabrication process creates the dual structure (unless costly special processing is introduced) each transistor type (PFET or NFET) also exists as an element in circuits that do not use the transistor. For example, when the PFET is desired, the NFET remains connected in the circuit and contributes noise or some other parasitic element to the operation, and vice versa.

### SUMMARY

According to an embodiment of the present disclosure, a microelectronic structure is provided. The microelectronic structure includes a nanosheet transistor device stack having a first transistor device stacked on a second transistor device. The first transistor device includes a source and drain. The second transistor device includes terminal connections. A gate is shared between the first transistor device and the second transistor device. The first transistor device is configured to conduct a current between the drain and the source based on a voltage on the gate. The terminal connections of the second transistor device are vestigial irrespective of a voltage applied to the gate, such that the second transistor device is always passive.

According to another embodiment of the present disclosure, a microelectronic structure is provided. The microelectronic structure includes a stacked nanosheet transistor device. The stacked nanosheet transistor device includes an active field effect transistor (FET), and a passive FET. The active FET includes a source and drain. A gate is shared by the active FET and the passive FET. The passive FET includes terminal connections. The active FET is configured to actively process a signal and the passive FET is configured to mitigate parasitic elements when the active FET is processing the signal.

According to another embodiment of the present disclosure, a microelectronic structure is provided. The microelectronic structure includes a stacked nanosheet transistor that includes a first FET and a second FET. A gate is shared by the first FET and the second FET. The first FET is always active and configured to pass a current between a drain and a source of the first FET based on a voltage on the gate. The second FET is a vestigial device that is always passive. The second FET includes terminal connections that are floating, grounded, or half-clamped.

The techniques described herein may be implemented in a number of ways. Example implementations are provided below with reference to the following figures.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all of the components or steps that are illustrated. When the same numeral appears in different drawings, it refers to the same or like components or steps.

FIG. 1 is a perspective view of a microelectronic structure in a conventional semiconductor device.

FIG. 2 is a perspective view of a microelectronic structure, consistent with embodiments of the present disclosure.

FIG. 2A is schematic view of the microelectronic structure of FIG. 2, consistent with embodiments of the present disclosure.

FIG. 3 is a perspective view of a microelectronic structure, consistent with embodiments of the present disclosure.

FIG. 3A is schematic view of the microelectronic structure of FIG. 3, consistent with embodiments of the present disclosure.

FIG. 4 is a perspective view of a microelectronic structure, consistent with embodiments of the present disclosure.

FIG. 4A is a schematic view of the microelectronic structure of FIG. 4, consistent with embodiments of the present disclosure.

FIG. 4B is a schematic view of the microelectronic structure of FIG. 4, according to another embodiment.

FIG. 5 is a perspective view of a microelectronic structure, consistent with embodiments of the present disclosure.

FIG. 5A is a schematic view of the microelectronic structure of FIG. 5, consistent with embodiments of the present disclosure.

FIG. 5B is a schematic view of the microelectronic structure of FIG. 5, according to another embodiment.

FIG. 6 is a schematic view of a microelectronic structure, according to another embodiment.

### DETAILED DESCRIPTION

### Overview

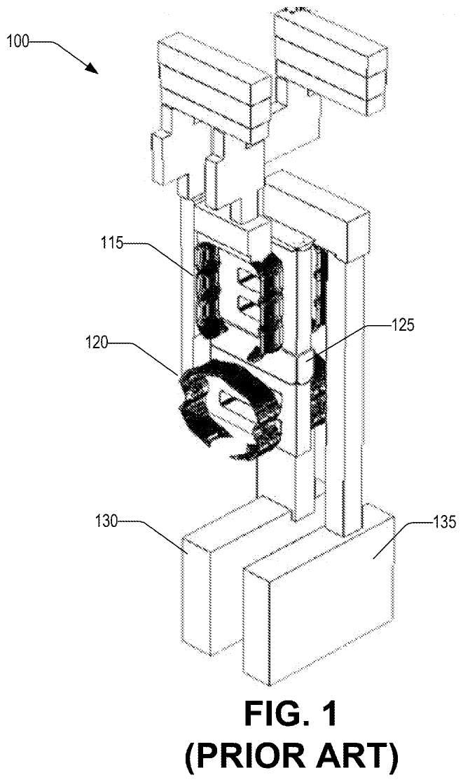

In general, a microelectronic structure is provided that includes pairs of stacked nanosheet field effect transistors (FET) for analog applications that comprises alternating one FET as active and the other FET as passive. In nanosheet stacked FET devices, the FETs are usually paired where one of the FET devices is a PFET and the other device is an NFET. As shown in FIG. 1, a stacked nanosheet device 100 is shown that includes a PFET drain 115 and an NFET drain 120 associated with a shared gate 125. The NFET source is connected to the buried ground bus 130, while the PFET source is connected to the buried VDD power bus 135. Normally, both the PFET and NFET elements are active when the device 100 is in operation, although typically in combinatorial logic one of the devices is turned on and the other is turned off.

For more complex circuit combinations, some applications may want only a PFET connection or an NFET connection. For example, in analog applications, sometimes a PFET is wanted and sometimes an NFET is wanted. The structure disclosed in FIG. 1 may be unsuitable since the transistor pair has both FET types active at any given time. Embodiments of the subject technology disclose a structure that allows only one of the PFET or NFET transistors to be active while the other transistor device is passive. The passive device becomes a parasitic element, present for the purpose of structural and process compatibility with the commonplace configuration for combinatorial logic gates One or both of the terminals for the passive device may be left floating or tied to a power supply. As will be appreciated, the structure of the subject device permits more combinations of connections that want only a PFET or an NFET connection. Moreover, some features of the embodiments mitigate the parasitic contribution from the passive device during operation.

According to an embodiment of the present disclosure, a microelectronic structure is provided. The microelectronic structure includes a nanosheet transistor device stack having a first transistor device stacked on a second transistor device. The first transistor device includes a source and drain. The second transistor device includes terminal connections. A gate is shared between the first transistor device and the second transistor device. The first transistor device is configured to conduct a current between the drain and the source based on a voltage on the gate. The terminal connections of the second transistor device are vestigial irrespective of a voltage level applied to the gate, such that the second transistor device is always passive. Although microelectronic structures may sometimes have devices that are paired, sometimes only one of the two devices is needed. The other device becomes a source for parasitic signals. The vestigial status of terminals in one transistor device provides circuits with the ability to process signals for one type of transistor yet mitigates the parasitic signal from the other type of transistor.

According to one embodiment, which can be combined with one or more previous embodiments, the second transistor device is floating. Floating the second transistor device disconnects the second transistor device from leeching from the input signal passing through the gate or contributing a parasitic signal to the signal being processed.

According to one embodiment, which can be combined with one or more previous embodiments, the second transistor device is clamped to a power source. Clamping the second transistor device provides another way to cut off parasitic elements from contributing to the signal being processed.

According to one embodiment, which can be combined with one or more previous embodiments, the first transistor device is a PFET and the second transistor device is an NFET. The embodiment provides structures that can process applications calling for PFET-only circuit elements.

According to one embodiment, which can be combined with one or more previous embodiments, the terminal connections on the second transistor device are grounded. Grounding the terminals removes the second transistor device from providing any negative contribution to the signal being processed by the PFET.

According to one embodiment, which can be combined with one or more previous embodiments, the terminal connections on the second transistor device are half-clamped; that is, one terminal is floating and the other is clamped. The embodiment can be used most effectively for low threshold voltage devices while still minimizing parasitic contributions from the lower transistor device.

According to one embodiment, which can be combined with one or more previous embodiments, the first transistor device is an NFET and the second transistor device is a PFET. The embodiment provides structures that can process applications calling for NFET-only circuit elements.

According to one embodiment, which can be combined with one or more previous embodiments, the terminal connections on the second transistor device are floating. Floating the second transistor device disconnects the second transistor device from leeching from the input signal passing through the gate or contributing a parasitic signal to the signal being processed.

According to one embodiment, which can be combined with one or more previous embodiments, the terminal connections on the second transistor device are clamped. Clamping the second transistor device provides another way to cut off parasitic elements from contributing to the signal being processed.

According to one embodiment, which can be combined with one or more previous embodiments, the width of the second transistor device is smaller than a width of the first transistor device. Controlling the width of the passive device further controls the possible parasitic contribution from the passive device. A smaller width means less parasitic contribution from the passive device.

According to another embodiment of the present disclosure, a microelectronic structure is provided. The microelectronic structure includes a stacked nanosheet transistor device. The stacked nanosheet transistor device includes an active field effect transistor (FET), and a passive FET. The active FET includes a source and drain. A gate is shared by the active FET and the passive FET. The passive FET includes terminal connections. The active FET is configured to actively process a signal and the passive FET is configured to mitigate parasitic elements when the active FET is processing the signal. Microelectronic structures may sometimes have devices with paired FETs. Sometimes only one of the two FETs is needed. The other FET becomes a source for parasitic signals. The structure provides circuits with the ability to process signals for one type of FET yet mitigates the parasitic signal from the other FET.

According to one embodiment, which can be combined with one or more previous embodiments, the active FET is a PFET and the passive FET is an NFET. The embodiment provides structures that can process applications calling for PFET-only circuit elements.

According to one embodiment, which can be combined with one or more previous embodiments, the terminal connections are grounded. Grounding the terminals removes the lower transistor device from providing any negative contribution to the signal being processed by the PFET.

According to one embodiment, which can be combined with one or more previous embodiments, the terminal connections are half-clamped. The embodiment can be used for low threshold voltage applications while still minimizing parasitic contributions from the lower transistor device.

According to one embodiment, which can be combined with one or more previous embodiments, the active FET is an NFET and the passive FET is a PFET. The embodiment provides structures that can process applications calling for NFET only processing.

According to one embodiment, which can be combined with one or more previous embodiments, the terminal connections are floating. Floating the passive device disconnects the passive device from leeching from the input signal passing through the gate or contributing a parasitic signal to the signal being processed.

According to one embodiment, which can be combined with one or more previous embodiments, the terminal connections are clamped. Clamping the passive device provides another way to cut off parasitic elements from contributing to the signal being processed.

According to one embodiment, which can be combined with one or more previous embodiments, the terminal connections are half-clamped; that is, one terminal is left floating and the is clamped to a power supply. The embodiment is most effective when with a low threshold voltage device while still minimizing parasitic contributions from the lower transistor device.

According to one embodiment, which can be combined with one or more previous embodiments, a width of the PFET is smaller than a width of the NFET. By making the width of the PFET smaller than the width of the NFET, the contribution of any parasitic signal from the passive element can be reduced by design.

According to another embodiment of the present disclosure, a microelectronic structure is provided. The microelectronic structure includes a stacked nanosheet transistor that includes a first FET and a second FET. A gate is shared by the first FET and the second FET. The first FET is always active and configured to pass a current between a drain and a source of the first FET based on a voltage on the gate. The second FET is a vestigial device that is always passive. The second FET includes terminal connections that are floating, grounded, or half-clamped. As may be appreciated, when a signal passes through a shared gate in a nanosheet device, the FET not being used may still be nominally active and becomes a source of parasitic qualities. By making the second FET passive, the parasitic qualities can be controlled and mitigated.

According to one embodiment, which can be combined with one or more previous embodiments, the second FET has a width that is smaller than a width of the first FET. By making the width of one FET smaller than the width of the other FET, the contribution of any parasitic signal from the passive element can be reduced by design.

In the following detailed description, numerous specific details are set forth by way of examples in order to provide a thorough understanding of the relevant teachings. However, it should be apparent that the present teachings may be practiced without such details. In other instances, well-known methods, procedures, components, and/or circuitry have been described at a relatively high-level, without detail, in order to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the direction of the Figures being described. Since components of embodiments of the disclosure can be positioned in a number of different directions, the directional terminology is used for purposes of illustration and is in no way limiting. Thus, it will be understood that the spatially relative terminology is intended to encompass different directions of the device in use or operation in addition to the direction depicted in the figures. For example, if the device in the figures is turned over, elements described as “below” or “beneath” other elements or features would then be oriented “above” the other elements or features. Thus, for example, the terms “below” or “stacked” can encompass both an orientation that is above, as well as, below. Similarly, an element described as “on top of” of another element may mean either that the element is positioned above and is not necessarily in direct contact with the underlying element. The device may be otherwise oriented (rotated 90 degrees or viewed or referenced at other directions) and the spatially relative descriptors used herein should be interpreted accordingly.

As used herein, the terms “lateral”, “planar”, and “horizontal” describe an orientation parallel to a first surface of a chip or substrate. In the disclosure herein, the “first surface” may be the top layer of a semiconductor device where individual circuit devices are patterned in the semiconductor material.

As used herein, the term “vertical” describes an orientation that is arranged perpendicular to the first surface of a chip, chip carrier, chip substrate, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together. The phrase “electrically connected” does not necessarily mean that the elements must be directly in physical contact together-intervening elements may be provided between the “connected” or “electrically connected” elements.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. Nor does describing an element as “first” or “second”, etc. necessarily mean that there is an order or priority to any of the elements. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope. It should be appreciated that the figures and/or drawings accompanying this disclosure are exemplary, non-limiting, and not necessarily drawn to scale.

It is to be understood that other embodiments may be used, and structural or logical changes may be made without departing from the spirit and scope defined by the claims. The description of the embodiments is not limiting. In particular, elements of the embodiments described hereinafter may be combined with elements of different embodiments.

### Definitions

Stacked Nanosheet Transistor: a type of transistor that includes multiple, horizontal, nanometers-thin sheets stacked atop one another.

Stacked-FET Technology: a form of semiconductor technology in which transistors are stacked atop one another, typically of opposite types, and sharing a common gate.

Floating: an electrical element that is disconnected from a circuit.

Clamped: an electrical element that is connected (tied-off) to a power source and limited to a fixed voltage.

Effective width: width of the channel region controlled by the gate in a FET.

Vestigial: a structure in an electronic circuit that is electrically disconnected, rendering the structure inoperative for its typical electrical function in circuits.

### Example Device Architecture

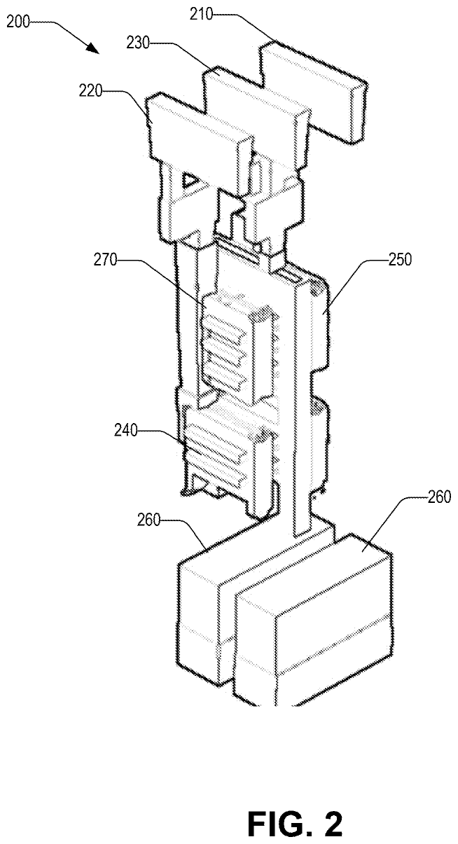

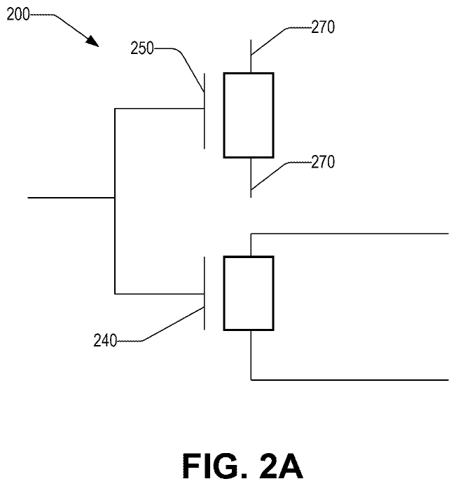

Referring now to FIG. 2 and FIG. 2A, the subject disclosure provides a microelectronic device 200 according to an embodiment. The microelectronic device 200 (and other embodiments disclosed below) provide analog operation to a circuit (not shown) in which the microelectronic device 200 resides. In general, embodiments include a first FET that is active when a signal passes through a shared gate to the first FET and a second FET that is passive when the first FET is active. Generally, the first FET processes any signal that is forwarded by the gate through the first FET's source and drain. The second FET may include vestigial terminal connections that are disconnected from their typical function. For example, irrespective of a voltage (high or low) applied to the gate, the second FET is rendered passive since the signal will always be drawn (pulled up or down) through the first FET. For example, the microelectronic device 200 includes an active NFET 240 and a floating PFET 250. In some embodiments, the NFET 240 is lower transistor device and the PFET 250 is an upper transistor device within the microelectronic device 200. The NFET 240 and PFET 250 share a gate 230 in common.

The microelectronic device 200 may include an NFET drain connection 210 and an NFET source connection 220. Some embodiments include backside power rails 260 connected to other elements in the circuit. As can be seen in the illustration, the PFET portion of the NFET/PFET pair of the microelectronic device 200 is not connected to any other electronic element. For example, the PFET 250 may include terminal connections 270 on a side of the PFET 250. The terminal connections 270 are electrically open-ended (i.e., not connected to anything). In operation, when signals pass through the NFET drain connection 210 and the NFET source connection 220, the NFET 240 becomes active (i.e., a signal is being processed through the NFET 240), and the PFET 250 becomes a passive device. As will be appreciated, the microelectronic device 200 provides a device for NFET-only type applications, yet mitigates the normally present parasitic elements by floating the PFET 250. Floating the PFET 250 does not allow for a signal to pass through the PFET 250 and reduces the parasitic capacitance on the circuit.

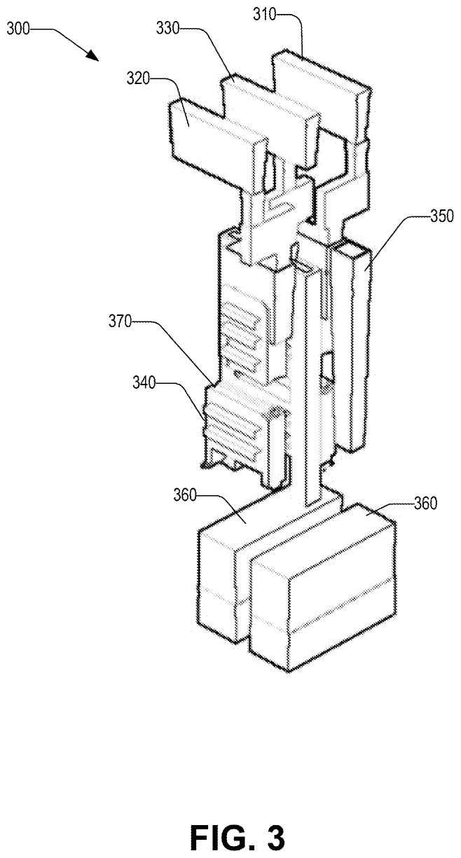

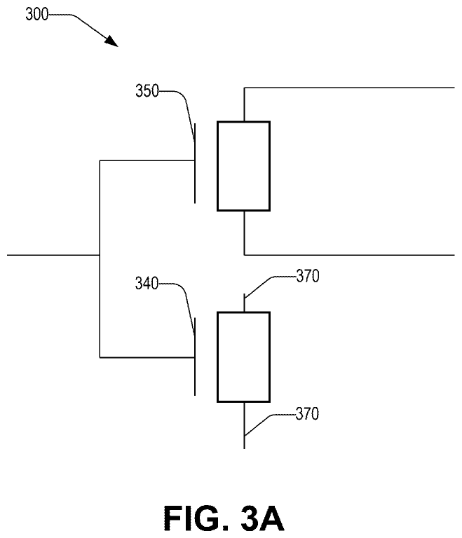

FIG. 3 and FIG. 3A show a microelectronic device 300, consistent with embodiments. The microelectronic device 300 includes an active PFET 350 and a floating NFET 340. In some embodiments, the PFET 350 is an upper transistor device and the NFET 340 is a lower transistor device within the microelectronic device 300. The PFET 350 and NFET 340 share a gate 330 in common. The microelectronic device 300 may include a PFET drain connection 310 and an PFET source connection 320. Some embodiments include backside power rails 360 connected to other elements in the circuit. As can be seen in the illustration, the NFET portion of the NFET/PFET pair of the microelectronic device 300 is not connected to any other electronic element. For example, the NFET 340 may include terminal connections 370 on a side of the NFET 340. The terminal connections 370 are electrically open-ended (i.e., not connected to anything). In operation, when signals pass through the PFET drain connection 310 and the PFET source connection 320, the PFET 350 becomes active (i.e., a signal is being processed through the PFET 350), and the NFET 340 becomes a passive device.

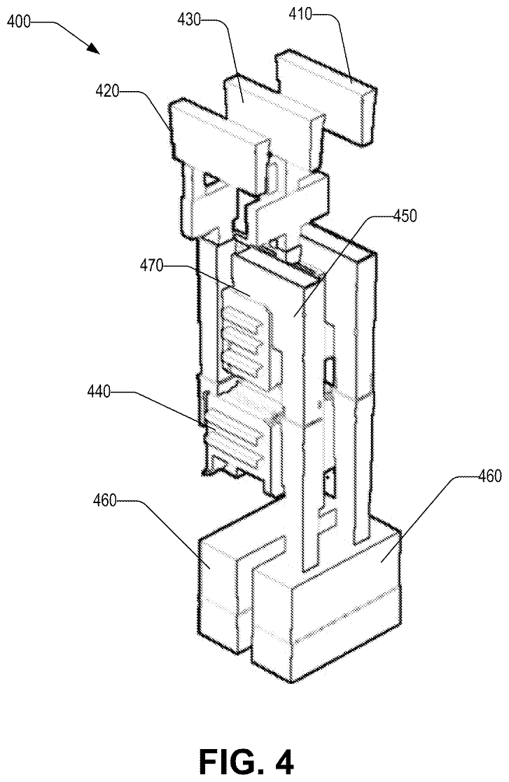

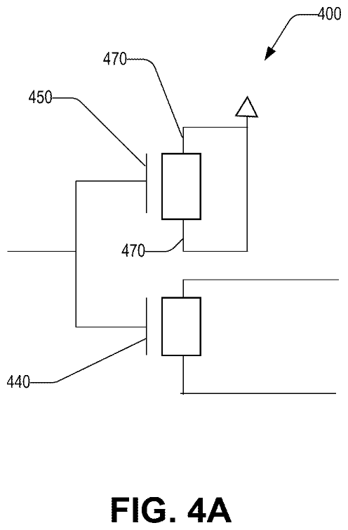

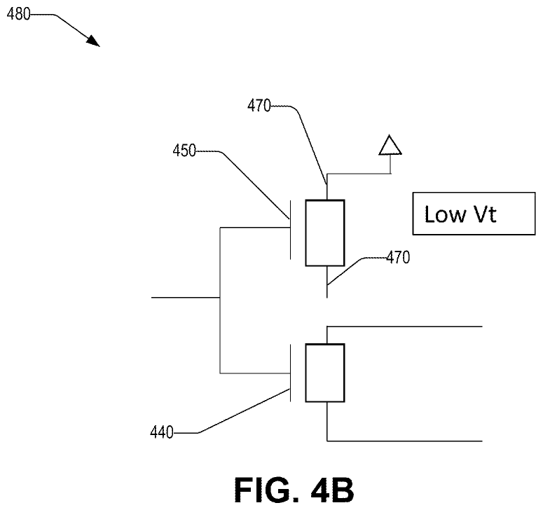

FIGS. 4 and 4A show a microelectronic device 400, consistent with embodiments. The microelectronic device 400 includes an active NFET 440 and a clamped PFET 450. In some embodiments, the NFET 440 is a lower transistor device and the PFET 450 is an upper transistor device within the microelectronic device 400. The NFET 440 and PFET 450 share a gate 430 in common. The microelectronic device 400 may include an NFET drain connection 410 and an NFET source connection 420. Some embodiments include backside power rails 460. Referring also now to FIG. 4A, a schematic of the circuit for the microelectronic device 400, consistent with the embodiment of FIG. 4 is shown. The PFET portion of the NFET/PFET pair of the microelectronic device 400 is clamped or tied-off to power. For example, the PFET 450 may include terminal connections 470 on a side of the PFET 450. The terminal connections 470 are electrically connected to a line connected to a power source in the circuit, in this illustration one of the backside power rails 460. In operation, when signals pass through the NFET drain connection 410 and the NFET source connection 420, the NFET 340 becomes active (i.e., a signal is being processed through the NFET 440), and the PFET 450 becomes a passive device, and the connection to the power rail may suppress noise coupling in the circuit.

FIG. 4B shows a microelectronic device 480 similar to the micro electronic device 400, except that the PFET 450 is half-clamped. For example, the bottom terminal 470 is physically open. For example, the circuit may be for a low threshold voltage device. For low threshold voltage devices in particular, the PFET 450 does not need to be fully clamped.

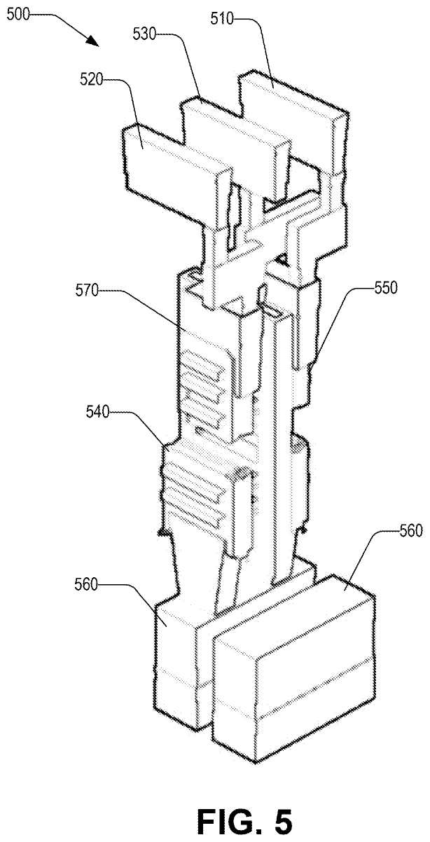

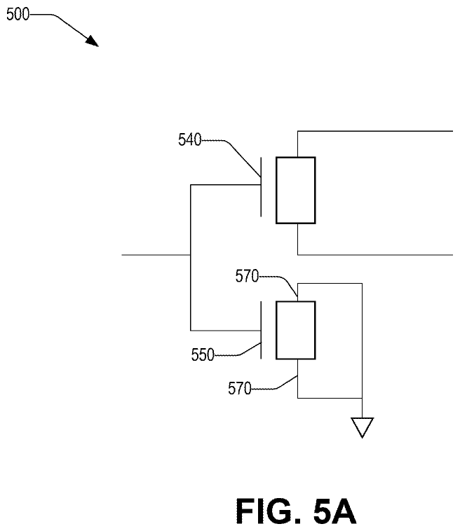

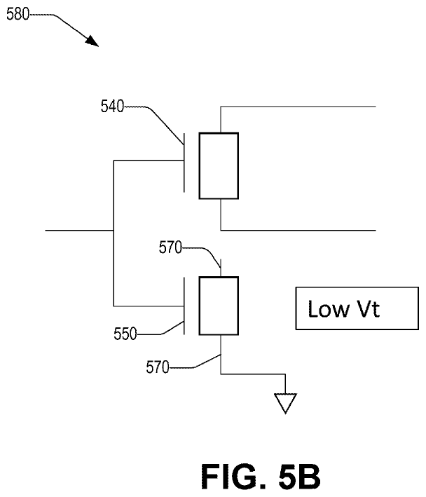

FIGS. 5 and 5A show a microelectronic device 500, consistent with embodiments. The microelectronic device 500 includes an active PFET 550 and a grounded NFET 540. In some embodiments, the PFET 540 is an upper transistor device and the NFET 550 is a lower transistor device within the microelectronic device 500. The PFET 540 and NFET 550 share a gate 530 in common. The microelectronic device 500 may include a PFET drain connection 510 and a PFET source connection 520. Some embodiments include backside power rails 560, in this illustration connected to the passive NFET terminal 570.

In FIG. 5A, a schematic of the circuit for the microelectronic device 500, consistent with the embodiment of FIG. 5 is shown. The NFET portion of the NFET/PFET pair of the microelectronic device 500 is grounded. For example, the NFET 550 may include terminal connections 570. The terminal connections 570 which would normally be source and drain connections, are electrically grounded in the circuit. In operation, when signals pass through the PFET drain connection 510 and the PFET source connection 520, the PFET 540 becomes active (i.e., a signal is being processed through the PFET 540), and the NFET 550 becomes a passive device. As will be appreciated, the microelectronic device 500 is more noise immune and able to isolate noise from adjacent (nearby) devices. In addition, the signal processing provides a stable signal.

FIG. 5B shows a microelectronic device 580 similar to the micro electronic device 500, except that the NFET 550 is half-clamped. For example, the upper terminal 570 is physically open. The circuit may be most effective for a low threshold voltage device. For low threshold voltage, the NFET 550 does not need to be fully grounded.

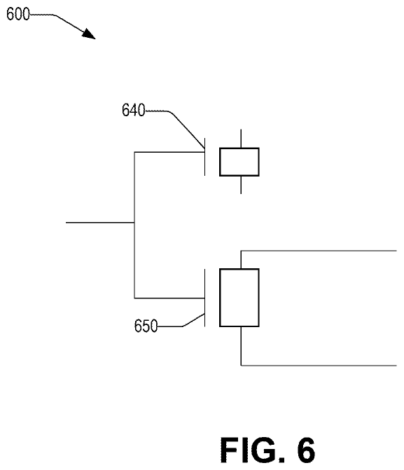

FIG. 6 shows a microelectronic device 600 similar to microelectronic device 200 where the NFET 650 is active and the PFET 640 is passive. The microelectronic device 600 is an embodiment where the passive PFET 640 is typically designed to have an effective width similar relative to the effective width of the active NFET 650. However, the effective width of the passive transistor may be made smaller relative to the active transistor to reduce any negative contribution to the device; as small as one-half to one-tenth, within practical process limits. As will be appreciated, by reducing the effective width of the passive device (PFET 640), any parasitic contribution from the passive device is further mitigated in addition to the effect of floating or clamping the passive device.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

The components, steps, features, objects, benefits and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits, and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

What is claimed is:

1. A microelectronic structure, comprising:
a nanosheet transistor device stack having a first transistor device stacked on a second transistor device, wherein:
the first transistor device includes a source and drain; and
the second transistor device includes terminal connections; and
a gate shared between the first transistor device and the second transistor device, wherein:
the first transistor device is configured to conduct a current between the drain and the source based on a voltage on the gate; and
the terminal connections of the second transistor device are vestigial irrespective of a voltage applied to the gate, such that the second transistor device is always passive.

2. The microelectronic structure of claim 1, wherein the terminal connections the second transistor device are floating.

3. The microelectronic structure of claim 1, wherein the terminal connections of the second transistor device are clamped to a voltage level.

4. The microelectronic structure of claim 1, wherein the first transistor device is a PFET and the second transistor device is an NFET.

5. The microelectronic structure of claim 4, wherein the terminal connections of the second transistor device are grounded.

6. The microelectronic structure of claim 5, wherein the terminal connections of the second transistor device are half-clamped.

7. The microelectronic structure of claim 1, wherein the first transistor device is an NFET and the second transistor device is a PFET.

8. The microelectronic structure of claim 7, wherein the terminal connections of the second transistor device are floating.

9. The microelectronic structure of claim 7, wherein the terminal connections of the second transistor device are clamped.

10. The microelectronic structure of claim 6, wherein an effective width of the first transistor device is smaller than an effective width of the second transistor device.

11. A microelectronic structure, comprising:
a nanosheet transistor device stack that includes:
an active field effect transistor (FET) having a source and drain; and
a passive FET having terminal connections; and
a gate shared by the active FET and the passive FET, wherein:
the active FET is configured to actively process a signal and the passive FET is configured to mitigate parasitic elements when the active FET is processing the signal.

12. The microelectronic structure of claim 11, wherein the active FET is a PFET and the passive FET is an NFET.

13. The microelectronic structure of claim 11, wherein the terminal connections are half-clamped.

14. The microelectronic structure of claim 11, wherein the active FET is an NFET and the passive FET is a PFET.

15. The microelectronic structure of claim 14, wherein the terminal connections are floating.

16. The microelectronic structure of claim 14, wherein the terminal connections are clamped.

17. The microelectronic structure of claim 14, wherein the terminal connections are half-clamped.

18. The microelectronic structure of claim 14, wherein an effective width of the PFET is smaller than an effective width of the NFET.

19. A microelectronic structure, comprising:
a stacked nanosheet transistor that includes a first FET and a second FET; and
a gate shared by the first FET and the second FET, wherein:
the first FET is always active and configured to pass a current between a drain and a source of the first FET based on a voltage on the gate;
the second FET is a vestigial device that is always passive; and
the second FET includes terminal connections that are floating, grounded, or half-clamped.

20. The microelectronic structure of claim 19, wherein the second FET has an effective width that is smaller than an effective width of the first FET.
